(19) United States
(12) Patent Application Publication
(10) Pub. No.: US 2024/0249971 A1
(43) Pub. Date: Jul. 25, 2024

(54) WEIGHTED LIFT PIN CONSTRUCTIONS FOR SEMICONDUCTOR FABRICATION PROCESSING

(71) Applicant: ASM IP Holding B.V., Almere (NL)

(72) Inventors: Rohan Vijay Rane, Tempe, AZ (US); Ankit Kimtee, Phoenix, AZ (US); Todd Robert Dunn, Cave Creek, AZ (US); Akshay Phadnis, Phoenix, AZ (US); Kyle Fondurulia, Phoenix, AZ (US); Sudhanshu Biyani, Tempe, AZ (US); Mun Peow Wong, Phoenix, AZ (US)

(21) Appl. No.: 18/417,655

(22) Filed: Jan. 19, 2024

Related U.S. Application Data
(60) Provisional application No. 63/440,726, filed on Jan. 24, 2023.

(51) Int. Cl. H01L 21/687

(52) U.S. Cl. CPC H01L 21/68742

(57) ABSTRACT

Weighted lift pin constructions as disclosed may be used with a semiconductor fabrication processing apparatus. The weighted lift pin constructions comprise a lift pin and a weight element disposed along an end of the lift pin. The weight element is removably retained on the lift pin by a retaining element that may be a clip element, an O-ring element, and differently configured lift pin and weight element threaded sections. When the clip element or O-ring element used, the weight element includes a collar adjacent an end of an opening in the weight element to accommodate placement of the clip or O-ring element therein as retained on the lift pin to thereby maintain axial placement of the lift pin relative to the weight element. Such maintained axial placement may also be achieved by interference locked engagement between differently configured lift pin and weighted element threaded sections.

### CROSS-REFERENCE TO RELATED APPLICATIONS

This application is a nonprovisional of, and claims priority to and the benefit of, U.S. Provisional Patent Application No. 63/440,726, filed Jan. 24, 2023 and entitled “WEIGHTED LIFT PIN CONSTRUCTIONS FOR SEMICONDUCTOR FABRICATION PROCESSING,” which is hereby incorporated by reference herein.

### FIELD

Weighted lift pin constructions as disclosed herein relate to weighted lift pins as used for semiconductor fabrication processing and, more specifically, to weighted lift pin constructions specially configured to facilitate ease of assembly in a reactor used for semiconductor fabrication processing, and promote reliable use during such semiconductor fabrication processing.

### BACKGROUND

The use of lift pins in semiconductor fabrication processing is known and in an example such lift pins are used for the purpose of contacting a substrate such as a semiconductor wafer and guiding placement, e.g., relative upward and downward movement, of the substrate onto a susceptor disposed in a reaction chamber for subsequent semiconductor processing, such as atomic layer deposition of materials, chemical treatment, or the like. Lift pins may be moved downwardly relative to the susceptor by gravity, e.g., using the weight of the lift pin itself. In certain types of semiconductor fabrication processing, the weight of the lift pin itself is not sufficient to ensure proper downward movement of the lift pin that may be due to the presence of material in through holes within which the lift pins are disposed, wherein the presence of such material may be the result of a material deposition process or the like. Accordingly, to address such issues, lift pins are also known to make use of springs or additional weight to ensure proper downward gravitational movement during semiconductor fabrication processing.

Thus, lift pins comprising a weight element are known, and such weighted lift pins comprise the lift pin itself and a weight element that is attached to the lift pin to add sufficient weight to the lift pin to thereby ensure desired downward movement by gravity force. Such known weighted lift pins include those relying on a threaded engagement between the lift pin and the weight element, wherein the weight element has a threaded opening with threads complementary to those on the lift pin and the weight element is attached to the lift pin by rotating and threading the weight element onto the lift pin. An issue that exists with this type of known weighted lift pin construction is the creation of metal shavings, particles, or the like that may occur when the lift pin and weight element are threadably engaged and connected. The creation and presence of such metal shavings or particles in the reaction chamber is not desired as such presents a contaminant to the semiconductor fabrication process.

Also, in the event that a set screw is not used to secure the weight element on the lift pin, the weight element may rotate or spin during subsequent semiconductor fabrication processes, which may result in improper operation of the weighted lift pin that can result in damage to the semiconductor wafer being processed and/or to the surrounding processing equipment. This may also ultimately result in the weight element separating from the lift pin, which may also cause damage to the semiconductor wafer and/or damage to the semiconductor processing equipment, and that will require downtime for weighted lift pin replacement. In the event that a set screw is used, the installation of the set screw is difficult, tedious, and time consuming as the task is performed in the reaction chamber where available working space is very limited, thereby requiring that the small set screw be carefully handled. If the set screw is accidently dropped, the process of extracting the set screw from within the reaction chamber requires that additional and time consuming steps be taken. Further, such weighted lift pins making use of the set screws are known to be difficult to removed and replace because of the set screws seizing due to thermal cycling during use over the course of multiple semiconductor fabrication processes.

It is, therefore, desired that a weighted lift pin for use in semiconductor fabrication processing be specifically constructed in a manner that avoids the above-described issues associated with known weighted lift pins to thereby enable such weighted lift pins to be easily installed in the confines of a reaction chamber, and to ensure repeated reliable weighted lift pin function and service life when compared to such known weighted lift pins.

### SUMMARY

Weighted lift pin constructions as disclosed herein are configured for use with a semiconductor fabrication processing apparatus. In an example, the apparatus comprises a reaction chamber, and a susceptor disposed in the reaction chamber for placing a semiconductor substrate thereon, wherein the susceptor has through-holes in an axial direction of the susceptor. Weighted lift pins as disclosed herein comprises lift pins that are slidably disposed in the respective through-holes for lifting the semiconductor substrate over the susceptor. The lift pins comprise a weight element disposed along an end of the lift pin that is disposed below the susceptor (thereby forming the weighted lift pin construction), wherein the weight element is removably retained on the lift pin by a retaining element. In an example, the retaining element may comprise or be selected from the group consisting of a clip element, an O-ring element, and differently configured lift pin and weight element threaded sections. In an example, the lift pins may be made from molybdenum. The lift pins may be treated to have a lubricating layer of molybdenum disulfide on an outside surface to facilitate axial movement of the lift pin in the through holes.

In an example, the weighted lift pin weight element may comprise a flange section that extends a distance from a top axial end of the weight, and a sleeve section that extends axially away from the flange section to a bottom axial end of the weight. In such example, the sleeve section has an outer diameter sized smaller than the flange section, and the weight element comprises an opening extending axially at least a partial distance from the top axial end to accommodate placement of the lift pin therein. In such an example, the sleeve section extends along a majority of a total axial length of the weight element.

In an example, the weighted lift pin weight element comprises an opening that extends axially therethrough from a top axial end to a bottom axial end. In such example, the lift pin is configured adjacent a bottom axial end to accommodate placement of one of the clip element or the O-ring element thereon and. When installed on the lift pin, the clip element and the O-ring element have an outside diameter sized larger than the opening adjacent the bottom axial end of the weight element to retain axial placement of the lift pin relative to the weight element. In such an example, the weighted lift pin weight element comprises a collar that is connected with the opening and that extends axially a partial length from a bottom axial end of the weight element. In an example, the collar has a diameter sized larger than the opening for accommodating placement of the clip element or the O-ring element therein as disposed on the lift pin. In such example, the lift pin comprises a surface feature adjacent the bottom axial end that operates to retain axial movement of the clip element or O-ring element relative to the lift pin.

In such example, when the retaining element is the clip element, the surface feature is provided by the bottom axial end having an outwardly flared configuration with a diameter sized greater than an inside diameter of the clip element. In an example, the clip element has a crescent-shaped configuration and may be formed from a ceramic material. In an example when the retaining element is the O-ring element, the surface feature comprises a recessed section that extends circumferentially around the lift pin adjacent the bottom axial end and is sized to accommodate placement of an inside diameter of the O-ring element therein. In an example, the O-ring element is configured to fit circumferentially around the lift pin within the recessed section of the lift pin, wherein the O-ring element has an outside diameter sized to fit in the sleeve and the outside diameter is sized smaller than the opening so that when the O-ring element is installed on the lift pin and placed into the weight element collar the axial placement of the weight element relative to the lift pin is retained. In an example, where the retaining element is the O-ring element, the lift pin comprises a radially inwardly tapered section extending from the recessed section to the bottom axial end to accommodate axial placement of the O-ring element onto the lift pin.

In an example, the weighted lift pin weight element opening comprises a threaded section that is configured differently than a threaded portion of the lift pin to cause the lift pin to form a locking engagement with the weight element when threadably engaged therebetween to retain axial placement of the weight relative to the lift pin. In such example, the threaded section of the weight element comprises a ramp surface or section that is configured differently than the threaded portion or section of the lift pin to provide the locking engagement to retain the desired axial placement of the weight relative to the lift pin.

Weighted lift pin constructions as disclosed herein are specially configured to enable weighted lift pins to be easily installed in the confines of a reaction chamber, and to ensure repeated reliable weighted lift pin function and service life when compared to the known weighted lift pins as described above.

### BRIEF DESCRIPTION OF THE DRAWINGS

These and other features and advantages of weighted lift pin constructions used for semiconductor fabrication processing as disclosed herein will be appreciated as the same becomes better understood by reference to the following detailed description when considered in connection with the accompanying drawings where:

FIG. 1A is a schematic cross-sectional view of an example weighted lift pin construction as disclosed herein in a first position for use in semiconductor fabrication processing;

FIG. 1B is a schematic cross-sectional view of the example weighted lift pin construction of FIG. 1A in a second position;

FIG. 2A is a perspective top view of an example weight element as used with the example weighted lift pin construction of FIGS. 1A and 1B;

FIG. 2B is a perspective bottom view of an example weight element as used with the example weighted lift pin construction of FIGS. 1A and 1B;

FIG. 3 is a schematic cross-sectional view of a section of the weighted lift pin construction of FIGS. 1A and 1B;

FIG. 4 is a schematic cross-sectional view of another example weighted lift pin construction as disclosed herein for use in semiconductor fabrication processing;

FIG. 5 is a perspective view the example weighted lift pin construction of FIG. 4 showing elements forming the same in an unassembled state;

FIG. 6 is a schematic top view of the example weighted lift pin construction of FIG. 4 showing an example weight element and example retaining clip element in an unassembled state;

FIG. 7 is a schematic cross-sectional view of another example weighted lift pin construction as disclosed herein for use in semiconductor fabrication processing;

FIG. 8 is a schematic cross-sectional view of the example weighted lift pin construction of FIG. 7; and

FIG. 9 is a schematic cross-sectional view of an enlarged section of the example weighted lift pin construction of FIG. 7.

### DETAILED DESCRIPTION

Weighted lift pin constructions as disclosed herein are generally configured to comprise a lift pin that is attached to a weight element through the use of a retaining element that is configured to promote easy attachment in the limited spatial confines of a reaction chamber used for semiconductor fabrication processing while also reducing or eliminating the possibility of producing metal shavings or particles that may enter the reaction chamber and be a source of contamination.

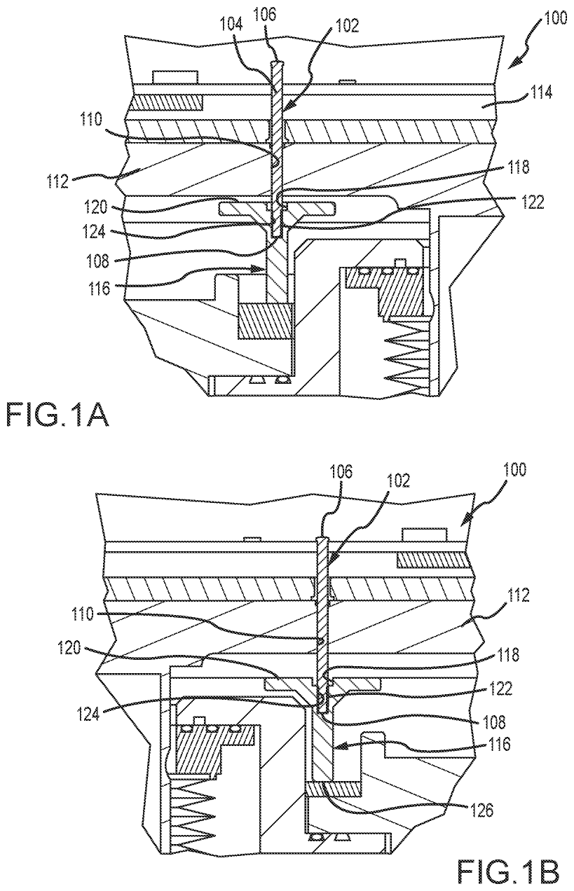

FIG. 1A illustrates a semiconductor fabrication processing apparatus 100 comprising an example weighted lift pin 102 as disclosed therein that is disposed within the apparatus. In an example, the weighted lift pin 102 comprises a lift pin 104 that extends axially from a top end 106 to a bottom end 108, wherein in an example the top end 106 is shaped to accommodate placement of a semiconductor wafer thereon to support the same. In an example, the top end 106 may be flat. In an example, the lift pin 104 has a cylindrical shape and is sized for placement within a through hole 110 that extends axially through a portion of device 112 in the semiconductor fabrication processing apparatus 100. In an example, the through hole 110 extends through a portion of a susceptor 112 that is disposed in a reaction chamber 114 of the apparatus 100. The through hole 110 may or may not include a bushing disposed therein and interposed between the lift pin 104 and the through hole 110. In an example, the through hole 110 is sized to permit free sliding axial up and down movement of the lift pin 104 therein.

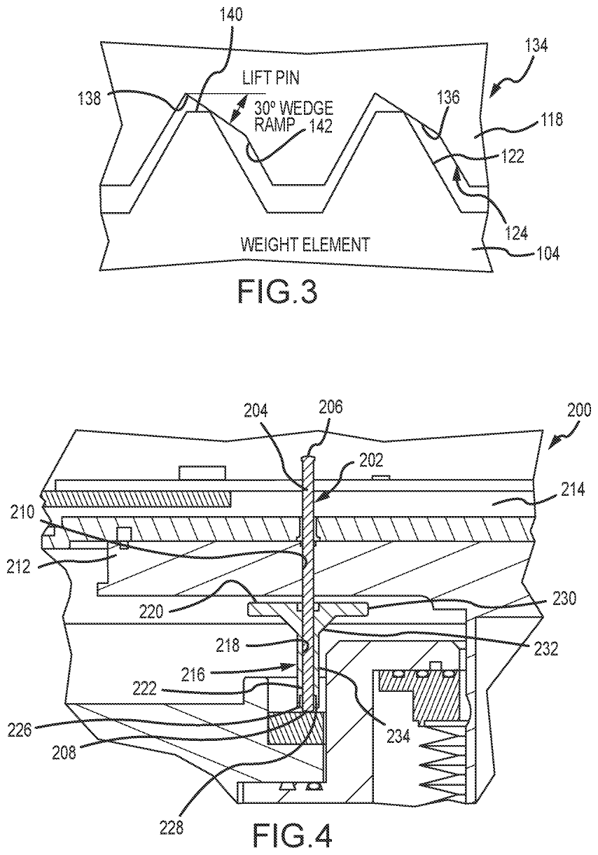

The lift pin top end 106 is positioned above the susceptor 112 to accept placement of a silicon wafer thereon. The lift pin 104 extends through the through hole 110 such that the bottom end 108 is disposed below the susceptor 112. A weight element 116 is attached to the lift pin 104 below the susceptor 112 and comprises an opening 118 disposed axially through a top end 120 of the weight element 116 that extends a partial depth therein. In an example, the weighted lift pin 102 comprises a retaining element configured to securely attach the weight element 116 to the lift pin 102. In an example, the retaining element is provided in the form of a threaded section 122 of the lift pin adjacent the bottom end 108 and a threaded section 124 of the weight element disposed in the opening that are specially configured to be noncomplementary so as to form an interlocked threaded engagement therebetween as described in better detail below with respect to FIG. 3.

FIG. 1A illustrates a state of the apparatus 100 where the weighted lift pin 102 is in an up position for accommodating placement of the silicon wafer thereon above the susceptor 112 for subsequent downward movement of the silicon wafer onto the susceptor 112 for fabrication processing in response to either upward movement of the susceptor 112 relative to the weighted lift pin, or to downward movement of the weighted lift pin 102 relative to the susceptor 112 caused by a device configured to move the weighted lift pin 102 separately from the susceptor 112.

FIG. 1B illustrates the apparatus 100 and the weighted lift pin 102 as described above and illustrated in FIG. 1A except that the weighted lift pin 102 is in a down position with the top end 106 moved axially closer to the susceptor 110. As noted above, the change in axial location of the of weighted lift pin 102 within the apparatus may occur by axial up or down movement of the susceptor 112 or by axial up and down movement of a device contacting a bottom end 126 of the weighted lift pin weight element 116. In an example, the lift pin 104 may have a diameter of from about 2 to 6 mm, and in a particular example has a diameter of approximately 4 mm, and may have an axial length of from about 75 to 150 mm, and in a particular example has an axial length of approximately 99 mm.

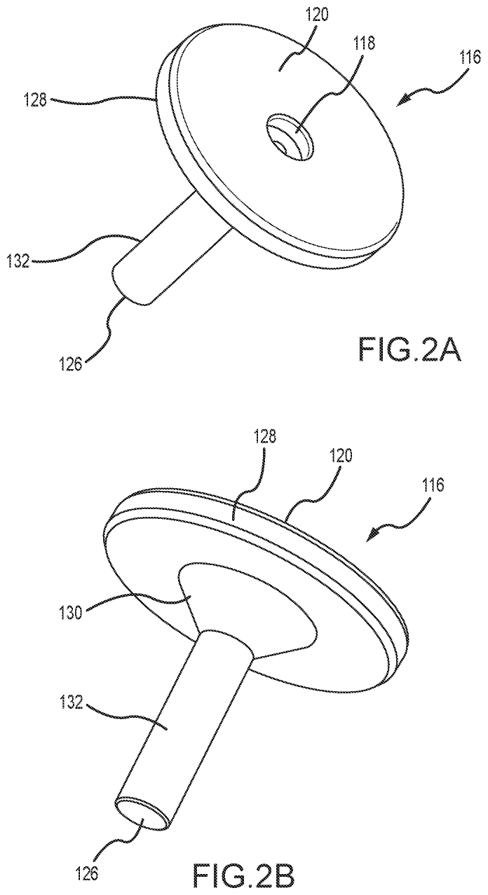

FIGS. 2A and 2B illustrate an example weight element 116 of the example weighted lift pin 102 disclosed and illustrated in FIGS. 1A and 1B comprising the top end 120 with the opening 118 extending therein. In an example, the weight element 116 is configured comprising a radially outwardly flared section 128 that extends from the top end 120 along an axial length. In an example, the flared section 128 has a diameter of from about 30 to 60 mm, and in a particular example has a diameter of approximately 45 mm. In an example, the flared section 128 extends an axial length of from about 2 to 15 mm, and in a particular example has an axial length of approximately 5 mm. In an example, the weight element 116 comprises a tapered section 130 (best shown in FIG. 2B) that extends axially a distance away from the flared section 128 and that decreases in diameter moving away from the flared section. In an example, the tapered section 130 has an initial diameter of from about 15 to 25 mm, and in a particular example has an initial diameter of approximately 20 mm, and has a final diameter of from about 3 to 9 mm, and in a particular example has a final diameter of approximately 6 mm. In an example, the tapered section 130 extends an axial length of from about 4 to 12 mm, and in a particular example has an axial length of approximately 8 mm. In an example, the weight element 116 comprises a sleeve section 132 that has a constant diameter that is the same as the tapered section 130 final diameter, wherein the sleeve section 132 extends axially from the tapered section 130 to the bottom end 126. In an example embodiment, the sleeve section has an axial length of from about 24 to 32 mm, and in a particular example of approximately 28 mm. While particular dimensions of the lift pin and the different sections of the weight element have been provided, it is to be understood that the dimensions of the lift pin and the weight element sections may vary depending from those disclosed, e.g., depending on the size or scale of the semiconductor fabrication processing apparatus, and that such variation in dimension of the lift pin and weight element is intended to be within the scope of the weighted lift pin construction as disclosed herein.

In an example, the weight element 116 is configured to have a weight that is similar to existing weight elements used with existing weighted lift pins so as to ensure the same amount of downward gravity force acts on the weighted lift pin as disclosed herein to permit retrofit use with existing semiconductor fabrication processing equipment, thereby avoiding the need to implement costly and time consuming equipment modifications or changes to promote easy interchangeable installation and use of the weighted lift pins as disclosed herein. In an example, the threaded section 124 of the opening 118 in the weight element 116 is disposed within the flange section 130, that operates to provide additional surrounding mechanical support thereto to ensure that during threaded engagement of the lift pin threaded section 122 therewith that the threaded section 124 does not defect radially outward to thereby promote the desired interlocking threaded engagement therebetween. In an example, the weight element 116 may be formed from a structurally rigid material suitable for use in the semiconductor fabrication process environment that does not deform, outgas, or otherwise introduce any form of contaminants, and that is resistant of pitting, crevice corrosion, and stress corrosion cracking at the temperatures and upon exposure to chemicals encountered during semiconductor processing. In an example, the weight element is formed from a metal or metal alloy material, and in a particular example the weight element is formed from an austenitic nickel-chromium-molybdenum-tungsten alloy.

FIG. 3 illustrates a section 134 of the weighted lift pin 102 disclosed above and illustrated in FIGS. 1A and 1B comprising the threaded section 124 of the weight element opening 118 and the threaded section 122 of the lift pin 104. In an example, at least one of the threaded sections is configured to not complement the other threaded section for the purpose of causing an interlocking engagement therebetween. In an example, the threaded section 124 of the weight element opening 118 is configured having a surface feature 126 that does not match or complement a surface feature of the lift pin threaded section 122. In a particular example, the surface feature 126 is provided in the form of a wedge ramp surface positioned along an apex portion 138 of the threads that does not match a flat apex 140 configuration of the lift pin thread. In an example, the wedge ramp surface has a radially inward directed angle of departure from the apex 138 of approximately 30 degrees. The wedge ramp surface extends axially from the thread apex an adjacent wall portion 142 of the thread. Configured in this manner, the wedge ramp surface 126 operates to form a binding interlocking engagement with the threaded section of the lift pin as the lift pin is threadably engaged with the weight element to thereby provide a self-locking connection between the lift pin 104 and weight element 116 without the need for a separate component such as a set screw or the like. While the weighted lift pin disclosed above and illustrated in FIGS. 1A, 1B, and 3 has illustrated a particular configuration of threaded sections to provide the above described interlocking threaded engagement feature, it is to be understood that variations or modifications of the same may exist, e.g., the surface feature providing the locking engagement may be configured differently than a wedge ramp and/or the surface feature may be provided on the threaded section of the lift pin rather than the on the threaded section of the weight element opening, and that all such variations or modifications that function to promote such threaded interlocking engagement are intended to be within the scope of weighted lift pins as disclosed herein.

FIG. 4 illustrates an illustrates a semiconductor fabrication processing apparatus 200 similar to that described above and illustrated in FIGS. 1A and 1B, comprising a reaction chamber 214 and susceptor 212 with through holes 210 extending axially therein, except that the example weighted lift pin 202 is configured differently. While the weighted lift pin 202 comprises a lift pin 204 that extends axially from a top end 206 to a bottom end 208, and is disposed within the through hole 210 in the susceptor 212, the configuration of the weight element 216 and the manner in which the lift pin 202 is attached to the weight element 216 is different than that described above for the weights lift pin illustrated in FIGS. 1A and 1B. In this example, the weight element 216 comprises an opening 218 that extends from a top end 220 axially though the weight element 216 to the bottom end 216, and the lift pin portion 222 is disposed within the opening 218 and a the lift pin bottom end 206 disposed adjacent the weight element bottom end 226. In this example, the weighted lift pin 220 functions in the same manner described above within the semiconductor fabrication processing apparatus to accommodate and move a silicon wafer axially relative to the susceptor.

In an example, the weighted lift pin 202 is configured to facilitate attachment between the lift pin 204 and the weight element 216 by use of a separate retaining element that does not involve threaded interlocking attachment between the lift pin and weight element. In an example, the lift pin 202 is configured to accommodate attachment of a retaining element 228 that is positioned adjacent the bottom end 208 and that is sized having an outside diameter that is greater than the diameter of the opening 218 through the weight element so as to retain or fix the weight element to the lift pin 202. In an example, the weight element 216 may be configured comprising a flared section 230, a tapered section 232, and a sleeve section 234 (with reference to FIG. 4) as described above and illustrated in FIGS. 2A and 2B). In an example, the lift pin 204 and the weight element 216 may have the same or similar dimensions to the example lift pin and weight element described above and illustrated in FIGS. 1A and 1B. In an example, the lift pin 204 may have an axial length greater than that described above for purposes of extending through the weight element opening 218. In an example, the lift pin 204 may have an axial length of from about 75 to 150 mm, and in a particular example has an axial length of approximately 99 mm. Again, it is understood that the dimensions of the lift pin and/or the weight element may vary from those disclosed and that such variations are intended to be within the scope of the weighted lift pin constructions disclosed herein.

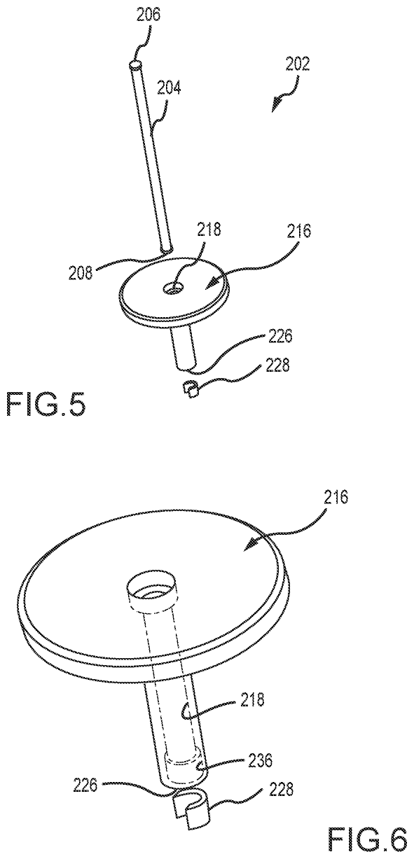

FIG. 5 illustrates the example weighted lift pin 202 of FIG. 4 in an unassembled state comprising the lift pin 202, the weight element 216, and the retaining element 228. In an example, the retaining element 228 is in the form of a crescent-shaped clip that is configured to slip or snap over a circumferential portion of the lift pin 202 adjacent the bottom end 208. In an example, the lift pin bottom end 208 is flared radially outward a distance so as to prevent the retaining clip 228 from slipping off of the lift pin (after the lift pin is inserted through the weight element opening 218 so that the bottom end 208 extends from the weight element bottom end 226 and the retaining clip is installed onto the lift pin 202 above the flared bottom end 208) as the retaining clip inside diameter is sized less than the outside diameter of the lift pin outwardly flared bottom end 208. The retaining clip may be formed from a material having a desired degree of structural rigidity that is capable of withstanding the elevated temperature conditions during semiconductor fabrication processing without outgassing or otherwise generating contaminate particles. In an example, the retaining claim may be formed from a metallic or ceramic material, and in a particular example is formed from a ceramic material. While a retaining element 228 having a particular shape has been described it is to be understood that differently shaped retaining elements may be used to function in the same or similar manner and that all such differently shaped retaining elements are intended to be within the scope of weight lift pins as disclosed herein.

FIG. 6 illustrates the example weight element 216 and retaining clip 228 described above and illustrated in FIGS. 4 and 5. In an example, the weight element 216 may comprise a collar 236 that extends axially from the bottom end 226 into the weight element. In an example, the collar 236 is axially aligned with the opening 218 and has an inside diameter that is sized larger than the inside diameter of the opening. In an example, the collar 236 is sized, e.g., having an inside diameter and an axial length, to accommodate placement of the retaining clip 228 therein as installed on the lift pin, which may be desired to ensure that the retaining clip 228 does not otherwise radially detach from the lift pin. Configured in the manner described above, the example weighted lift pin 202 making use of the retaining clip 228 enables easy installation to promote attachment of the weight element 216 to the lift pin 202 within the spatial confines of the semiconductor processing apparatus, does not require threaded engagement, and does not generate unwanted particles that may cause unwanted contamination during semiconductor fabrication processing.

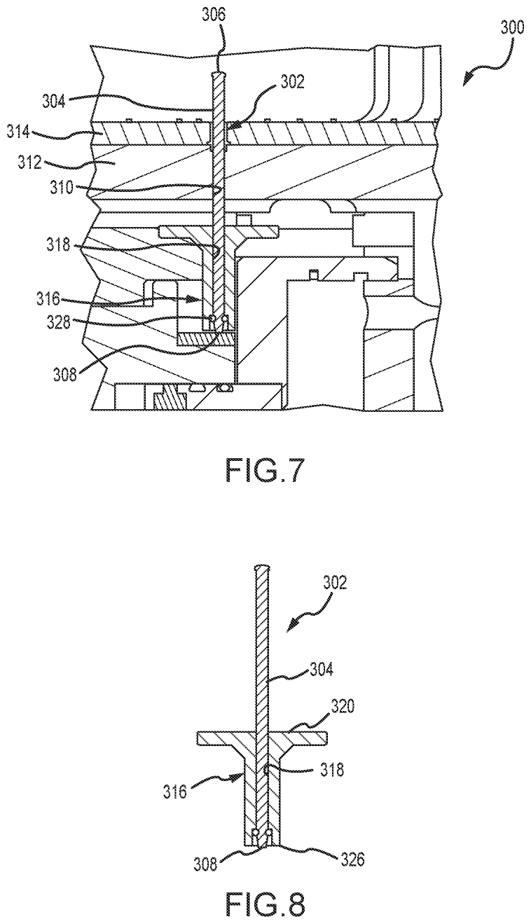

FIG. 7 illustrates a semiconductor fabrication processing apparatus 300 similar to that described above and illustrated in FIGS. 1A, 1B, and 4 comprising a reaction chamber 314 and susceptor 312 with through holes 310 extending axially therein, except that the example weighted lift pin 302 is configured differently. While the weighted lift pin 302 comprises a lift pin 304 that extends axially from a top end 306 to a bottom end 308, and is disposed within the through hole 310 in the susceptor 212, the configuration of the weight element 316 and the manner in which the lift pin 302 is attached to the weight element 316 is different than the earlier described and illustrated examples. Like the weighted lift pin example of FIG. 4, the example weighted lift pin 302 comprises a lift pin 304 that extends completely through an opening 318 in the weight element 316 and makes use of a separate retaining element 328 that is attached to the lift pin 304 adjacent the bottom end 308 to attach the lift pin 304 to the weight element 316.

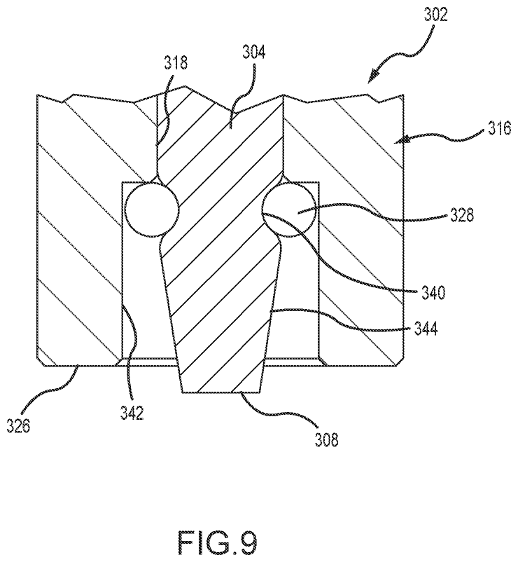

FIG. 8 illustrates the weighted lift pin 302 of FIG. 7 removed from the semiconductor processing apparatus for purposes of better showing the manner in which the lift pin 304 and weight element 316 are combined and attached. As noted, the lift pin 302 extends axially through the opening 318 that extends from the weight element top end 320 to the weight element bottom end 326. In an example, the retaining element 328 is configured to fit circumferentially around the outside diameter of the lift pin adjacent the bottom end 308 of the lift pin. As better shown in FIG. 9 that illustrates a section of the weighted lift pin 302 adjacent retaining element 328, the retaining element 328 has an outside diameter sized greater than a diameter of the opening 318 such that once installed around the lift pin the retaining element operates to attach the lift pin 304 with the weight element 316 so as to prevent the weight element from becoming axially detached from the lift pin.

Referring to FIG. 9, in an example, the lift pin 304 is configured comprising a recessed section 340 that extends radially inwardly a depth and that extends circumferentially around the lift pin 304. In an example, the recessed section 340 is located adjacent the bottom end 308 of the lift pin. In an example, the recessed section 340 has an outside diameter that is sized to accommodate placement of the retaining element 328 thereon in a manner that ensures that the retaining element 328 retains an axial placement position on the lift pin 304 in the recessed section 340. In an example, the retaining element 328 is provided in the form of an O-ring that is made from an elastomeric material. In an example, the O-ring 328 is made from an elastomeric material that has desired chemical resistance, and thermal stability, i.e., is capable of retaining its elastomeric properties and not deforming, and not outgassing or otherwise generating potentially contaminating particles when subjected to chemicals and/or the temperature conditions associated with the semiconductor fabrication process. In an example, the O-ring 328 is formed from a fluoropolymeric or fluoroelastomeric material, and in a particular example the O-ring is formed from a perforfluoroelastomer (FFKM).

In an example, the O-ring 328 is sized having an inside diameter that is smaller than the outside diameter of the lift pin 304. To ease and facilitate installation of the O-ring 328 onto the lift pin, the lift pin 304 may be configured having a tapered section 344 that extends axially from the bottom end 308 to the recessed section 340. In an example, the lift pin bottom end 308 has a reduced diameter relative to the remaining portion of the lift pin that is sized smaller than or similar to the inside diameter O-ring to permit easy installation of the O-ring over the bottom end 308. Extending from the bottom end 308, the tapered section gradually increases in diameter to a diameter that is the same as or similar to the remaining diameter of the lift pin aside from the recessed section. Configured in this manner, the tapered section functions to facilitate movement of the O-ring into the recessed section 340 by gradually elastically expanding the O-ring as the O-ring is moved axially therealong until the O-ring enters the recessed section 340 where the O-ring contracts around and becomes seated onto the lift pin 304. In an example, the O-ring 328 may have an inside diameter of from about 2 to 4 mm, and in a particular example has an inside diameter of approximately 2.5 mm. In an example, the lift pin 304 may have a diameter and length as described above for the example weighted lift pin illustrated in FIG. 4. In an particular example, the lift pin has an outside diameter of approximately 4 mm, the lift pin bottom end 308 has an outside diameter of approximately 2.75 mm, the recessed section 340 has an outside diameter of approximately 2.8 mm, and the tapered section 344 extends an axial length of approximately 6.5 mm from the lift pin bottom end 308.

In an example, the weighted lift pin 302 weight element 316 may comprise a collar 342 that extends axially from the bottom end 226 into the weight element. In an example, the collar 432 is axially aligned with the opening 318 and has an inside diameter that is sized larger than the inside diameter of the opening 318. In an example, the collar 342 is sized, e.g., having an inside diameter and an axial length, to accommodate placement of the O-ring 228 therein as installed on the lift pin 304, which may be desired to ensure that the O-ring does not otherwise radially detach from the lift pin. Configured in the manner described above, the example weighted lift pin 302 making use of the O-ring 328 enables easy installation to promote attachment of the weight element 316 to the lift pin 302 within the spatial confines of the semiconductor processing apparatus, does not require threaded engagement, and does not generate unwanted particles that may cause unwanted contamination during semiconductor fabrication processing.

Lift pins as disclosed herein may be made from structural materials that are chemically resistant and thermally stable so as to not degrade and/or outgas or otherwise generate unwanted particle matter when subjected to chemicals and the elevated temperatures associated with semiconductor fabrication processing. In an example, lift pins as disclosed herein may be formed from metals or metal alloys, and in a particular example may be formed from titanium or titanium alloy. In such an example, it may be desired to provide a coating or film on the lift pin for the purpose of providing desired enhanced surface properties such as wear resistance, chemical resistance, and the like. In an example where the lift pin is formed from titanium, it may be desired to provide a coating made from titanium nitride (TiN).

Lift pins as used both with weighted lift pin constructions as disclosed herein and as used in other lift pin configurations and construction may be formed in a manner that provides a reduced degree of surface friction or an increased degree of surface lubricity. In an example, it is desired that lift pins move freely within through holes during operation and do not stick or otherwise not smoothly travel up or down. Greases and other types of conventional lubricants are unsuited for use with lift pins used in semiconductor fabrication processing because of potential contamination in the reaction chamber. In an example embodiment, it is desired that the lift pins have a graphite-like surface structure provided by surface treatment that may be only a few micrometers thick. In an example, to achieve this purpose, it may be desired to form lift pins from molybdenum. In an example, the surface of the molybdenum lift pin may be treated to provide or form a molybdenum disulfide film or layer thereon, which operates to provide a lift pin surface having a reduced degree of friction and an improved degree of surface lubricity to ensure desired smooth operation of the lift pins while minimizing or avoiding possible contamination. In an example, the molybdenum disulfide coating or film may have a thickness of from about 0.1 to 10 micrometers. While particular materials have been disclosed for purposes of forming lift pins having reduced properties of surface friction, it is to be understood that other types of materials may be used to form and coat lift pins that operate to provide the same or similar function, and that all such materials are intended to be within the scope of lift pins having reduced surface friction as disclosed herein.

Although but a few example embodiments of weighted lift pins as used in semiconductor fabrication processing have been disclosed in detail above, those skilled in the art will readily appreciate that many modifications are possible in the example embodiments without materially departing from the intent and purpose of the example systems and method as disclosed herein. For example, while weight elements having a particular outer configuration have been disclosed it is to be understood that weight elements having different outer configurations that may be attached to the lift pin in the manner described are intended to be within the scope of weighted lift pins as disclosed herein. Accordingly, all such modifications of weighted lift pins are intended to be included within the scope of this disclosure as defined in the following claims.

What is claimed is:

1. A semiconductor fabrication processing apparatus comprising:
a reaction chamber;
a susceptor disposed in the reaction chamber for placing a semiconductor substrate thereon, the susceptor having through-holes in an axial direction of the susceptor;
lift pins slidably disposed in the respective through-holes for lifting the semiconductor substrate over the susceptor, wherein the lift pins comprise a weight element disposed along an end of the lift pin that is disposed below the susceptor, wherein the weight element is removably retained on the lift pin by a retaining element selected from the group consisting of a clip element, an O-ring element, and differently configured lift pin and weight element threaded sections.

2. The semiconductor fabrication processing apparatus of claim 1, wherein the weight element comprises a flange section extending a distance from a top axial end of the weight and a sleeve section that extends axially away from the flange section to a bottom axial end of the weight, wherein the sleeve section has an outer diameter sized smaller than the flange section, and wherein the weight element comprises an opening extending axially at least a partial distance from the top axial end to accommodate placement of the lift pin therein.

3. The semiconductor fabrication processing apparatus of claim 2, wherein the sleeve section extends along a majority of a total axial length of the weight element.

4. The semiconductor fabrication processing apparatus of claim 1, wherein the weight element comprises an opening that extends axially therethrough from a top axial end to a bottom axial end.

5. The semiconductor fabrication processing apparatus of claim 4, wherein the lift pin is configured adjacent a bottom axial end to accommodate placement of one of the clip element or the O-ring element thereon and, when installed on the lift pin, the clip element and the O-ring element have an outside diameter sized larger than the opening adjacent the bottom axial end of the weight element to retain axial placement of the lift pin relative to the weight element.

6. The semiconductor fabrication processing apparatus of claim 5, wherein the weight element comprises a collar that is connected with the opening and that extends axially a partial length from a bottom axial end of the weight element, wherein the collar has a diameter sized larger than the opening, and wherein the collar is sized to accommodate placement therein of the clip element or the O-ring element as disposed on the lift pin.

7. The semiconductor fabrication processing apparatus of claim 5, wherein the lift pin comprises a surface feature adjacent the bottom axial end that operates to retain axial movement of the clip element or O-ring element relative to the lift pin.

8. The semiconductor fabrication processing apparatus of claim 7, wherein when the retaining element is the clip element, the surface feature is provided by the bottom axial end having an outwardly flared configuration with a diameter sized greater than an inside diameter of the clip element.

9. The semiconductor fabrication processing apparatus of claim 7, wherein when the retaining element is the O-ring element, the surface feature comprises a recessed section that extends circumferentially around the lift pin adjacent the bottom axial end and is sized to accommodate placement of an inside diameter of the O-ring element therein.

10. The semiconductor fabrication processing apparatus of claim 2, wherein the lift pin comprises a radially inwardly tapered section extending from the recessed section to the bottom axial end to accommodate axial placement of the O-ring element onto the lift pin.

11. The semiconductor fabrication processing apparatus of claim 1, wherein the weight element opening comprises a threaded section that is configured differently than a threaded portion of the lift pin to cause the lift pin to form a locking engagement with the weight element when threadably engaged therebetween to retain axial placement of the weight relative to the lift pin.

12. The semiconductor fabrication processing apparatus of claim 11, wherein the threaded section of the weight element comprises a ramp surface that is configured differently than the threaded portion of the lift pin to provide the locking engagement.

13. The semiconductor fabrication processing apparatus of claim 1, wherein the lift pin is made from molybdenum, and wherein the lift pin is treated to have a lubricating layer of molybdenum disulfide on an outside surface to facilitate axial movement of the lift pin in the through holes.

14. A weighted lift pin for use in a semiconductor fabrication processing apparatus comprising a reaction chamber, a susceptor disposed in the reaction chamber for placing a semiconductor substrate thereon and having through-holes in an axial direction of the susceptor, the weighted lift pin comprising:
a lift pin capable of being slidably disposed in the respective through-holes for lifting the semiconductor substrate over the susceptor;
a weight element connected with the lift pin and capable of being disposed below the susceptor, wherein the weight element comprises an opening that extends at least partially therethrough, wherein the weight element comprises a radially outwardly flared section at a top axial end of the weight element and a sleeve section having a reduced diameter relative to the flared section that extends to a bottom axial end of the weight element; and
a retaining element configured to retain axial placement of the weight element relative to the lift pin, wherein the retaining element is selected from the group consisting of a clip element, an O-ring element, and a ramped threaded element.

15. The weighted lift pin of claim 14, wherein the weight element comprises a collar that extends axially from the opening and adjacent the opening axial bottom end that is configured having a diameter larger than the opening.

16. The weighted lift pin of claim 15, wherein the clip element is configured to slide radially over the lift pin adjacent a bottom end of the lift pin, wherein the lift pin bottom end has a surface feature configured to prevent axial movement of the clip element beyond the bottom end.

17. The weighted lift pin of claim 16, wherein the clip element is has an outside diameter sized larger than the opening fit in the sleeve so that when the clip element is installed on the lift pin and placed into the weight element collar axial placement of the weight element relative to the lift pin is retained.

18. The weighted lift pin of claim 14, wherein the clip element has a crescent-shaped configuration and is formed from a ceramic material.

19. The weighted lift pin of claim 15, wherein the O-ring element is configured to fit circumferentially around the lift pin within a recessed section of the lift pin adjacent a bottom end of the lift pin, and wherein the O-ring element has an outside diameter sized to fit in the sleeve and the outside diameter is sized smaller than the opening so that when the O-ring element is installed on the lift pin and placed into the weight element collar axial placement of the weight element relative to the lift pin is retained.

20. The weighted lift pin of claim 14, wherein the weight element opening comprises a threaded section having a ramp section that is configured differently than a threaded section of the lift pin to provide a locking interference when the lift pin and the weight element are threadably engaged to retain axial placement of the weight element relative to the lift pin.
